(19) United States
(12) Patent Application Publication
(10) Pub. No.: US 2011/0049715 A1
(43) Pub. Date: Mar. 3, 2011

(54) METHOD FOR DEPOSITING METAL OXIDE FILMS

(76) Inventors: Carlo Taliani, Bologna (IT); Petr Nozar, Bologna (IT)

(21) Appl. No.: 12/809,326

(22) PCT Filed: Dec. 19, 2007
(86) PCT No.: PCT/EP2007/064158

§ 371 Date: Oct. 26, 2010

(51) Int. Cl. H01L 23/532; H01L 21/768

(52) U.S. Cl. 257/749; 438/609; 257/E23.155; 257/E21.575

(57) ABSTRACT

A method for depositing a metal oxide film on a surface of a supporting body for the film, comprising the steps of: —providing a deposition chamber; —providing a pulsed beam of electrons and plasma in the deposition chamber; —supplying a supporting body in the deposition chamber, the supporting body having a deposition surface; —providing a target body made of a material which comprises the metal oxide in the deposition chamber, the target body having a target surface; —forming a plume of metal oxide ablated from the target surface by means of the impact of the pulsed beam of electrons and plasma against the target surface; and —depositing a metal oxide film on the deposition surface by means of the contact of the plume with the deposition surface.

### TECHNICAL FIELD

The invention relates to a method for depositing metal oxide films, to metal oxide films which can be obtained with such method, and to devices which contain such films. In particular, the invention relates to a method for depositing thin films of transparent conducting oxides (TCO) on surfaces of flexible materials and on surfaces of rigid materials which are preferably transparent.

### BACKGROUND ART

Metal oxide films, particularly thin metal oxide films which combine conduction and transparency properties and zinc oxide, zinc oxide doped with aluminum (AZO), lithium oxide (LZO), and other dopants, have been used extensively as transparent conducting electrodes in optoelectronic devices such as solar cells and flat panel displays (FPD), surface heaters in motor vehicle windows, lenses of cameras and mirrors, and also as materials for heat-reflecting transparent windows for buildings, lamps and solar collectors. They are also used extensively as an anode contact in organic light emitting diodes (OLEDs).

Several deposition methods are known and are used to grow these films, particularly TCO, including chemical vapor deposition (CVD), magnetron sputtering (arc- or radio frequency-based), thermal evaporation, and spray pyrolysis. These techniques require a complex process for preparing and using the initial materials from which the oxides then form in the environment of a deposition chamber. These techniques further require rather high temperatures of the substrate and/or of the subsequent thermal treatments and therefore do not allow to use plastic substrates, which would be damaged or even melted by high temperatures.

The method of growing by using pulsed lasers has been shown to exceed this limitation. Moreover, the pulsed laser deposition method (PLD) has yielded satisfactory results as regards the uniformity of the film and the chemical purity of the conducting transparent oxides deposited by means of this technique. However, the cost of laser sources poses important problems in the use of this method on an industrial level as regards the cost of purchasing the apparatus, the cost of production and system maintenance, and the effectiveness of the ablation process, since the PLD method, which uses photons as energy carriers for ablation, is not suitable for depositing transparent oxides (poor interaction of the photons with transparent material), and scalability.

Where flexibility and safety are important, glass cannot be used, since it is very fragile and too heavy, especially for large screens. These disadvantages can be overcome by using plastic surfaces or metal sheets, which can be very light and flexible. The development of an advanced OLED technology based on plastic or metal sheet supports requires a transparent conducting oxide material to be grown directly on plastics or on an organic emitting layer for the geometry of the metallic sheet. Passive and active matrix displays, such as liquid crystal displays (LCDs) and electroluminescent organic displays, will benefit greatly from the use of flexible surfaces.

If it is instead necessary to deposit TCO films over the emitting organic layer in OLEDs, the sputtering technique cannot be used to grow the electrode film, since energy species at more than 100 eV originating from the sputtering target damage the organic layer.

The method currently applied to deposit transparent conducting oxide films on plastic surfaces by sputtering produces a rough surface morphology and a high resistivity, which degrades the performance of OLEDs.

Accordingly, there is a great need for conducting transparent thin films on flexible surfaces which have a smooth surface, high optical transparency and low electrical resistivity and are suitable for use in OLEDs, and for methods for producing such films.

### DISCLOSURE OF THE INVENTION

The aim of the present invention is to provide metal oxide films, particularly thin films of transparent conducting oxides (TCO), preferably on flexible surfaces, which have a smooth surface, high optical transparency and low electrical resistance, and a method for producing them.

Another object of the present invention is to provide a method which allows to grow films made of TCO material directly on plastics or over an emitting organic layer, for use in passive and active matrix displays such as liquid crystal displays (LCDs) and electroluminescent organic displays which benefit greatly from the use of flexible surfaces, and for use in advanced OLED technology based on plastic supports or metal sheets.

This aim and these and other objects which will become apparent from the description that follows are achieved by a method according to the present invention for depositing a metal oxide film on a surface of a supporting body for said film, which comprises the steps of:

providing a deposition chamber;

providing a pulsed beam of electrons and plasma in said deposition chamber;

supplying a supporting body in said deposition chamber, said supporting body having a deposition surface;

providing a target body made of a material which comprises said metal oxide in said deposition chamber, said target body having a target surface;

providing a plume—a cloud of plasma (ionized hot gas) of metal oxide ablated from said target surface by means of the impact of said pulsed beam of electrons and plasma against said target surface;

depositing a metal oxide film on said deposition surface by means of the contact of said plume with said deposition surface.

In a preferred embodiment of the present invention, the metal oxide is a transparent conducting oxide, particularly a metal oxide selected from the group constituted by zinc oxide, zinc oxide doped with aluminum, such as a material composed of 90% to 100% by weight of ZnO and 10% to 0% by weight of Al.

The support used in the method according to the present invention for the deposition of the film can be a rigid support or a flexible support and can be a support made of a solid inorganic material, such as glass, quartz, and ZnSe, CdS, different types of metal and inorganic semiconductor, et cetera, or it can be a support made of solid organic material, a material selected from the group constituted by polymers such as polyesters, polyolefines, polyimides, phenolic resins, polyanhydrides, conducting polymers, conjugated polymers, fluoropolymers, silicone rubbers, silicone polymers, biopolymers, copolymers, block copolymers such as polycarbonate, PTFE, PET, PNT, PEDOT, polyaniline, polypyrrole, polythiophenes, polyparaphenylenes, (PPV), polyfluorenes, and molecular solids like molecular semiconductors, molecular crystals, molecular thin films, molecular dyes, such as AlQ3, thiophene oligomers, PPV oligomers, pentacene, tetracene, rubrene, NPB, fullerenes, carbon nanotubes and fullerides.

In a particularly preferred embodiment of the present invention, the deposited metal oxide film is a thin film, even of nanometer-scale thickness, of a transparent conducting oxide (TCO), and the support on which the film is deposited is a flexible support (i.e., a support which can be rolled up without damaging it).

The flexible supports used in the method according to the present invention can be made for example of a solid organic material, such as polycarbonate, PTFE, PET, AlQ3, T6, T7, PEDOT, PPV, αNPB, et cetera, or can be a metallic sheet.

The film or thin film of transparent conducting oxide (TCO) can be a film or thin film of transparent conductive oxide, particularly a metal oxide selected from the group constituted by zinc oxide, zinc oxide doped with aluminum, such as a material composed of up to 100% to 90% by weight of ZnO and 0% to 10% by weight of Al.

Another aspect of the present invention relates to a metal oxide film, particularly a thin film of transparent conducting oxide, which can be obtained by means of the method according to the present invention.

Another aspect of the present invention relates to a method for depositing a film of a metal oxide doped with a doping agent on a surface of a supporting body for said film, comprising the steps of:

providing a deposition chamber;

providing a first and a second pulsed beam of electrons and plasma in said deposition chamber;

supplying a supporting body in said deposition chamber, said supporting body having a deposition surface;

providing in said deposition chamber a first and a second target body, said first target body being made of a material which comprises said metal oxide, said second target body being made of a material which comprises said doping agent, said first target body having a first target surface and said second target body having a second target surface;

providing a plume of metal oxide ablated from said first target surface by means of the impact of said first pulsed beam of electrons and plasma against said first target surface, and a plume of said doping agent ablated from said second target surface by means of the impact of said second pulsed beam of electrons and plasma against said second target surface; and

depositing simultaneously said metal oxide and said doping agent on said deposition surface by means of the contact of said plume of metal oxide and of said plume of doping agent with said deposition surface, thereby a film of said metal oxide doped with said doping agent is obtained on said deposition body.

In one embodiment of this aspect of the invention, the metal oxide used in this method is, for example, type-p ZnO and the doping agent is, for example, a Li containing compound, as Li2O.

In another embodiment of this aspect of the invention, the metal oxide used is ZnO and the doping agent comprises magnetic species.

### BRIEF DESCRIPTION OF THE DRAWINGS

The invention is described in greater detail with reference to the figures that follow.

FIG. 1a: diagram of the electron beam source of the pulsed plasma deposition PPD device.(the current “trigger” is external). The electron beam source will be also designated herein as PPD gun, electron gun or gun.

FIG. 1b: ablation effect and plasma generation of PPD on a zinc oxide target (both the primary plasma of the electron pulse in the glass capillary and the secondary plasma of target material created by means of the microexplosion produced by the arrival of the packet of electrons on the surface of the target can be seen).

FIG. 2: schematic description of the ablation process (the picture on the left describes the situation of the arrival of the packet of electrons on the surface of the target and the image on the right describes the situation of microexplosion of the surface, i.e., the ablation of the material).

FIG. 3: ZnO film resistivity as a function of the oxygen pressure in the deposition chamber and of the temperature of the substrate, in which the optimum deposition parameters can be identified with respect to the minimum of resistivity ρ=0.6 mΩ-cm (p=6×10⁻⁵ mbar, T=300° C.).

FIG. 4: example of the measurement of transparency for wavelengths from 400 to 800 nm of a ZnO film. The oscillations caused by the flat and parallel arrangement of the film surfaces can be observed; the gray curve is a polynomial fit in order to determine the average value of transparency in each point of the wavelength range.

FIG. 5: example of the measurement of transparency for wavelengths in the IR range of a ZnO film. The film was deposited on a ZnSe crystal for reasons of transparency of the substrate in the IR range.

FIG. 6: dependency of the transparency of ZnO film for the wavelength λ=550 nm (visible range) on the deposition parameters. A strong dependency of transparency at this wavelength on deposition parameters is not observed. A weak minimum of transparency can be seen for temperatures above 400° C.

FIG. 7: dependency of the transparency of ZnO film for the wavelength λ=750 nm (infrared range) on the deposition parameters. Transparency in the IR follows the electrical resistivity in the most evident form: the minimum of transparency corresponds approximately to the minimum of resistivity.

FIG. 8: example of the morphology of a ZnO film deposited on a glass substrate at the temperature T=300° C. and at an oxygen pressure p=5·10⁻⁵ mbar. The film demonstrates the low resistivity of 1.11 mΩ-cm and a low roughness of 8 nm.

FIG. 9: example of the measurement of transparency for wavelengths from 400 to 800 nm of an AZO film.

FIG. 10: scheme of the two-gun PPD system; 1—deposition chamber, 2—target of the PPD gun 1, 3—target of the PPD gun 2, 4—sample (deposited thin film), 5—PPD gun 1 as disclosed in the FIG. 1, 6—PPD gun 2 as described in the FIG. 1.

FIG. 11: picture of the working two-gun PPD system.

### WAYS OF CARRYING OUT THE INVENTION

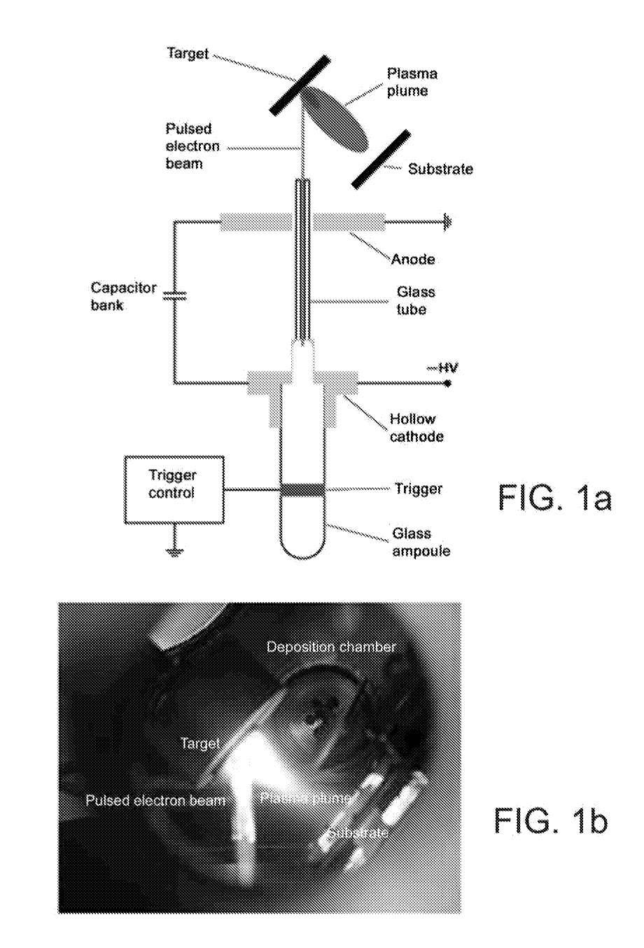

A schematic representation of an apparatus in which the method according to the first aspect of the present invention can be provided is shown in FIG. 1.

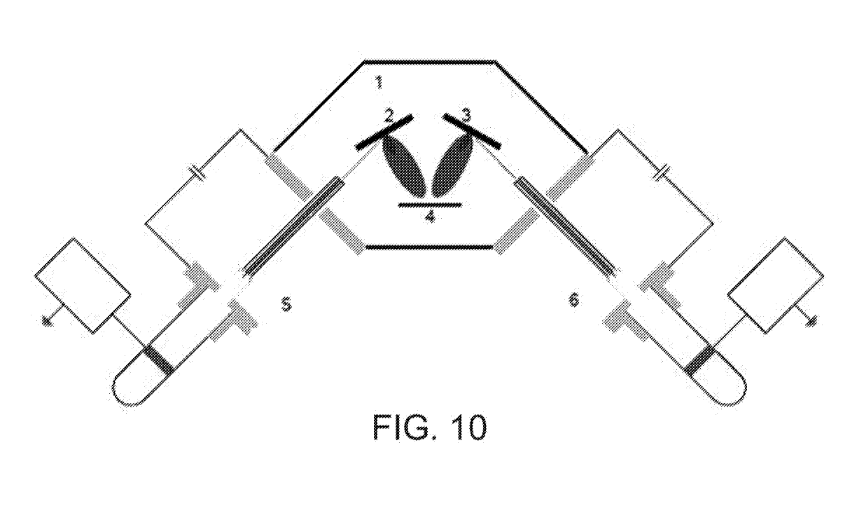

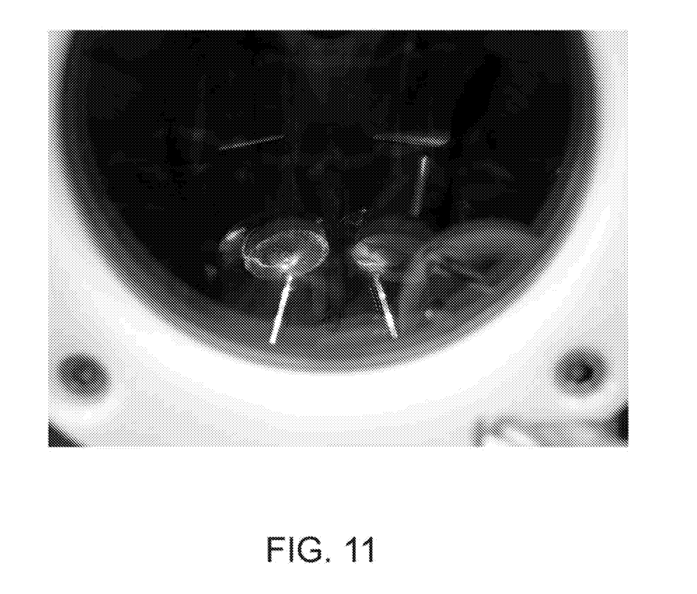

A schematic representation of an apparatus in which the method according to the second aspect of the present invention can be provided is shown in FIG. 10.

In one of its aspects, the present invention relates to the deposition of TCO by adapting a pulsed plasma deposition technique (PPD) based on the generation of high-energy electron pulses (up to 20 keV) and of plasma created by a working gas, such as oxygen, argon or nitrogen, at low pressure (from 10⁻⁶ to 10⁻² mbar), disclosed in WO2006/105955 and included herein by reference, together with an apparatus suitable for generating such pulses. The diagram of the apparatus used is shown in FIG. 1.

The working principle of the PPD system (which is not a part of the present invention) is similar to that one presented in the patent DE2804393 (U.S. Pat. No. 4,335,465 (A1)). However, the preferred embodiment of the PPD system used for the present invention is totally different from that one presented in the patents DE2804393 (U.S. Pat. No. 4,335,465 (A1)), U.S. Pat. No. 5,576,593A and the patent applications US2005012441A1 and US20070026160A1.

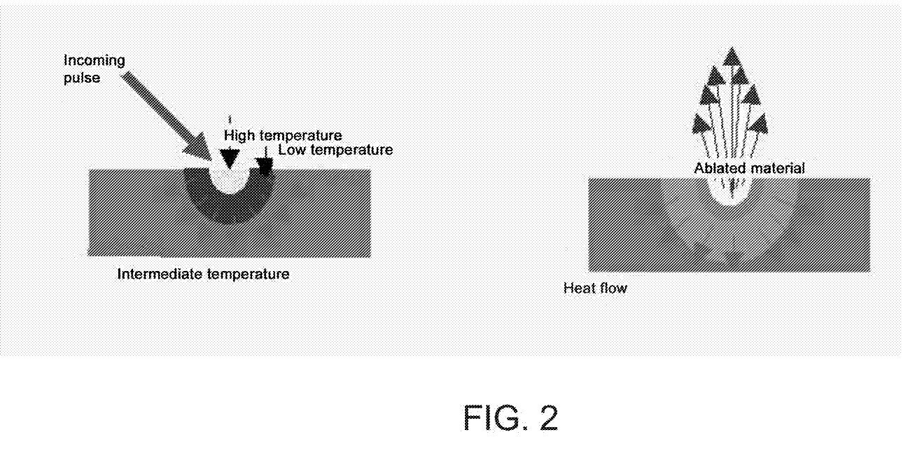

Electrons and plasma generated near the hollow cathode are subtracted and are accelerated with the electrical potential difference (up to 20 kV) between the hollow anode and the cathode and pass within the capillary or tube made of glass in an equipotential region between the anode and the target. By means of the impact of the packet (beam) of accelerated electrons and plasma on the surface of a target, the energy of the packet (beam) is transferred into the material of the target and causes its ablation, i.e., the explosion of the surface in the form of a plasma of the target material, also known as “plume”, which propagates in the direction of a substrate or support on which it is deposited (FIG. 2).

The ion conductivity of the low-pressure gases ensures electrostatic shielding of the space charge generated by the electrons. As a consequence of this, self-sustained beams can be accelerated with high energy and power density and directed against a target which is kept at GROUND potential, thus causing explosions below the surface of the target which generate the expulsion of material from such target (ablation or “explosive sublimation” process), thus forming the plume which propagates normally to the surface of the target.

The ablation depth is determined by the energy density of the beam, by the duration of the pulse, by the vaporization heat and by the heat conductivity of the material that constitutes the target as well as by the density of such target.

The material of the plume, during its path between the surface of the target and of the substrate, interacts with the carrier gas provided in the deposition chamber at low pressure (from 10⁻⁶ to 10⁻² mbar) and can be either left unchanged or slightly oxidized (carrier gas—oxygen), unchanged or slightly reduced (carrier gas—argon, nitrogen) or doped (as in the case of ZnO and the carrier gas mixture of nitrogen and NO). Recently it has been demonstrated (Krasik Ya. E., Gleizer S., Chirko K., Gleizer J. Z., Felsteiner J., Bernshtam V., Matacotta F. C., J. Appl. Phys., 99, 063303, (2006)) that only a small part (approximately 1%) of the electrons of the packet is accelerated by means of the full differential of potential between the cathode and the anode. The energy of most of the electrons does not exceed 500 eV. The deposition rate of the material (film growth rate) can be controlled by means of the frequency at which the electron packets are generated (repetition frequency), the difference of the potential between the cathode and the anode and the corresponding average current (approximately 3-5 mA) and by means of the distance between the target and the substrate.

The inventors of the present invention have found that in order to optimize the growth of the film on the substrate it is possible, among other things, to select and fix the suitable temperature of the substrate, for example by means of a heater incorporated in the substrate holder.

The inventors of the present invention have further found that by using pulsed beams of electrons and plasma it is possible to deposit metal oxide films, particularly films and thin films of transparent conducting oxides, on a rigid or flexible surface made of inorganic or organic material, which have a smooth surface, high optical transparency and low electrical resistivity and are suitable for use in devices such as OLEDs or solar cells.

Transparent conducting oxides have been deposited by means of the method according to the present invention with a purchase cost of the apparatus which is significantly lower than a PLD system, a production cost (in terms of cost of the electricity used) of no more than 10% of the production cost using PLD and with a system maintenance cost which is negligible with respect to the PLD system, with a higher ablation process efficiency than the PLD method, and with good scalability. The process according to the present invention in fact can be performed simply and inexpensively. The use of more than one gun to provide a system can be implemented easily. Moreover, this system does not exhibit the problems of adaptation of the dimensions of the apparatus to the dimensions of the required deposition process.

In the methods according to the present invention, the beam of electrons and plasma preferably has a pulsed energy from 500 eV to 50 keV, particularly from 5 keV to 20 keV.

In the deposition chamber there is a working gas, which is preferably selected from the group constituted by oxygen, argon, nitrogen and special mixtures such as methane in argon, hydrogen in argon, boranes, diboranes, ammonia, et cetera.

Preferably, a pressure from 10⁻⁶ to 10⁻² mbar, preferably from 10⁻⁵ to 5x 10⁻³ mbar, is maintained in the deposition chamber.

The beam of electrons and plasma used in the methods according to the present invention is preferably a pulsed beam of electrons and plasma generated at a frequency from 0.1 to 500 Hz, particularly from 1 to 19 Hz.

Preferably, the pulsed electron and plasma beam used in the methods according to the present invention is generated by using an average current from 1 to 50 mA, particularly from 1 to 5 mA.

The pulsed beam of electrons and plasma is a beam of electrons and plasma generated by using a potential difference between an anode and a cathode preferably from 500 V to 50 keV, particularly from 12 to 18 keV.

The methods according to the present invention can further comprise a step for adjusting a distance between said target surface and said deposition surface.

Preferably, the target surface and the deposition surface are arranged at a mutual distance of 5 to 500 mm.

The methods according to the present invention can further comprise the step for adjusting the temperature of said supporting body.

The temperature of the supporting body is preferably fixed in a range from ambient temperature to 550° C., more preferably at a temperature from ambient temperature to 350° C.

Moreover, the target body and the supporting body are positioned in the deposition chamber so that the deposition surface lies on the propagation path of the plume of metal oxide ablated from the target surface, which makes contact with the deposition surface so as to form by deposition the metal oxide film on the deposition surface.

The target body and/or the supporting body can be subjected to rotary motion during such deposition step in order to achieve more uniform deposition.

The thickness of the film deposited with the methods according to the present invention can be preset and controlled by means of a quartz-crystal balance. Preferably, the film deposited with the method according to the present invention is a thin film, preferably with a thickness in the range from 1 to 500 nm. More preferably, the thickness of the film deposited with the method according to the present invention is on the nanometer scale, particularly 200 nm.

All the considerations above are valid both for the method of the present invention using one PPD gun and the method of the present invention using two or more PPD guns and allowing simultaneous deposition on the deposition support of more substances.

The following exemplary of embodiments of the present invention are provided by way of non-limiting examples of the present invention.

### Deposition of ZnO

### Optimized Parameters of ZnO Deposition, Properties of Deposited Films

Experiments of deposition of ZnO films with the method according to the present invention have been performed with deposition parameters selected in the pressure range 1×10⁻⁵5×10⁻³ mbar of oxygen in the deposition chamber and a substrate temperature from 100 to 500° C. Optical microscope slides, quartz windows, ZnSe crystals and flexible sheets (PC, PTFE, PET) were used as substrates. The electron gun parameters were kept within the voltage ranges 12-18 kV, the power supply current within 3-5 mA, and the frequency of the electron discharges within 1-10 Hz. During deposition, the target was turned in order to prevent possible alteration of the chemical composition of the surface. The substrate was kept motionless during deposition and heated by using the halogen lamp. The temperature was measured by means of the thermocouple attached to the holder of the substrate, close to the substrate (between the substrate and the holder). The average deposition time was selected as 2 hours (the growth rate of the film thickness is on average 0.2 A/s).

The physical properties of the ZnO films were studied by measuring electrical resistivity (van de Pauw method), optical transparency (by means of the JASCO 550V spectrometer and the Bruker IFS-88 Fourier-transform interferometer) in the visible and infrared wavelength range, Hall effect, scanning electron microscopy and AFM (atomic force microscope).

The films deposited in the conditions specified above exhibit a thickness from 20 to 200 nm, an electrical resistivity from 1 mΩcm to 95 mΩcm, a transparency from 78 to 97%, a crystalline film morphology and a relatively low roughness, from 8 to 10 nm.

In particular, the following results were achieved for films of ZnO deposited by using the following conditions:

pulsed electron and plasma acceleration voltage V=−16 kV

deposition time t=2 hours

deposition frequency f=2 Hz

distance between target and substrate d=40 mm.

### Electrical Resistivity

Hall measurements have demonstrated that ZnO films are n-type semiconductors with a concentration of free charge carriers on the order of 10²⁰−10²¹ cm⁻³.

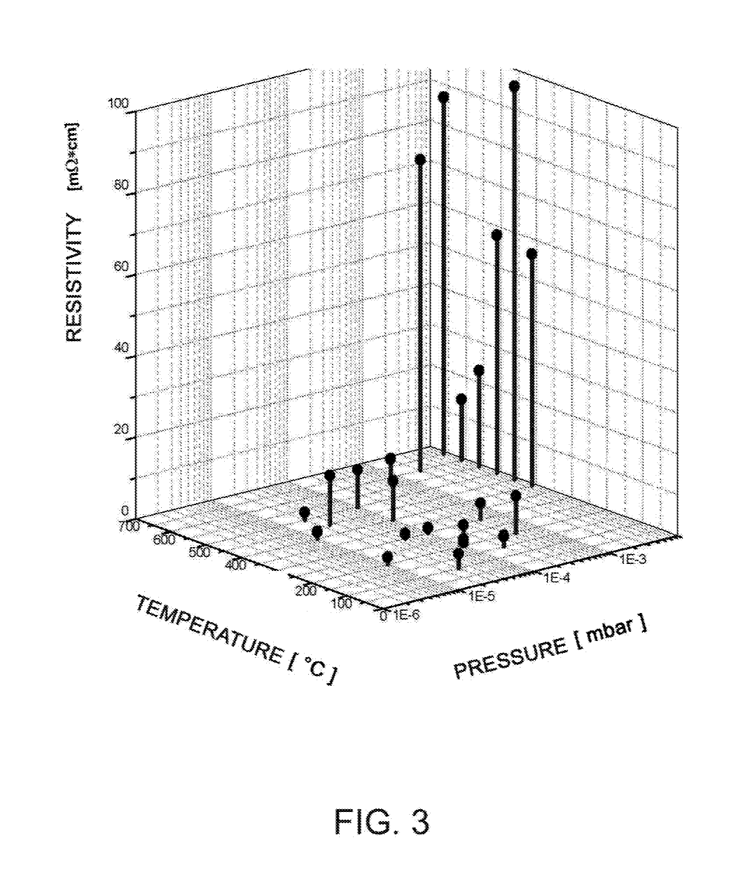

FIG. 3 summarizes the measurements of electrical resistivity for films deposited on a rigid support (glass) for different oxygen pressures and different substrate temperatures. As can be seen, the surface of the three-dimensional chart which corresponds to the values of resistivity for different combinations of parameters of the deposition demonstrates the minimum (value of resistivity ρ=0.6 mΩ-cm) neighborhood of the pressure values 6×10⁻⁵ mbar of oxygen and the temperature of the substrate 300° C.

Films deposited in the same conditions but at ambient temperature on a flexible substrate (PC) demonstrate the minimum resistivity value ρ=2.4 mΩ-cm.

### Transmittance

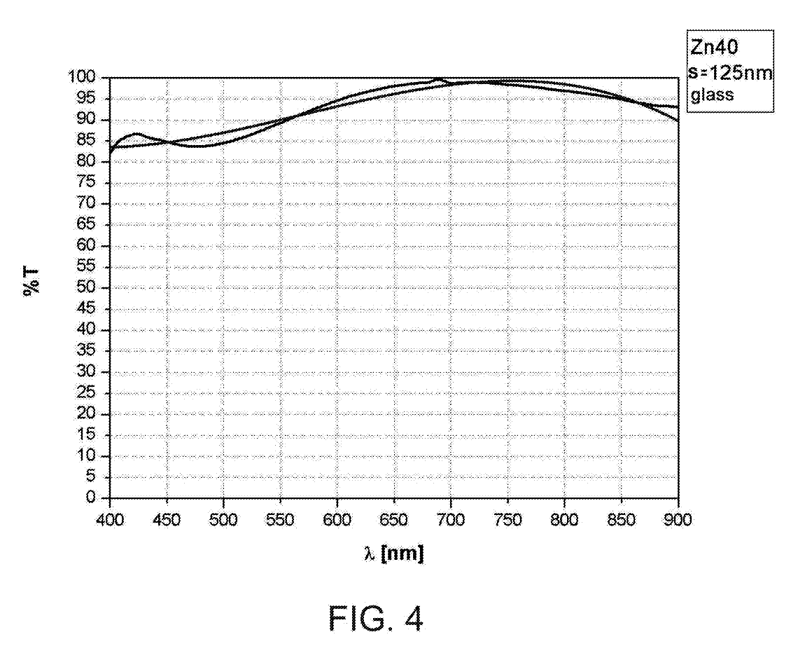

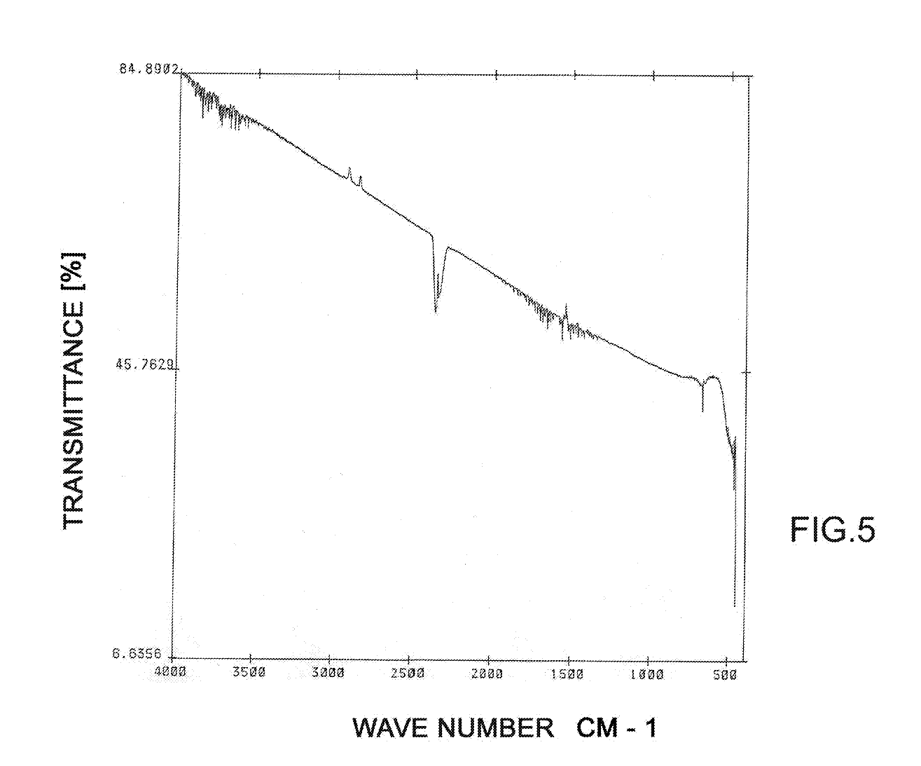

The examples of the measurements of transparency in UV-Vis are shown in FIGS. 4, 5, 6 and 7. The average value of the transparency of the ZnO films deposited on a rigid support (glass) at a pressure of 1*10⁻⁴ mbar and at a substrate temperature of 500° C. is T=93% in the 400-800 nm wavelength range (FIG. 4). In the wavelength range from 2.5 to 10 μm, the transparency of the film deposited on ZnSe crystal is from 85 to 47% (FIG. 5).

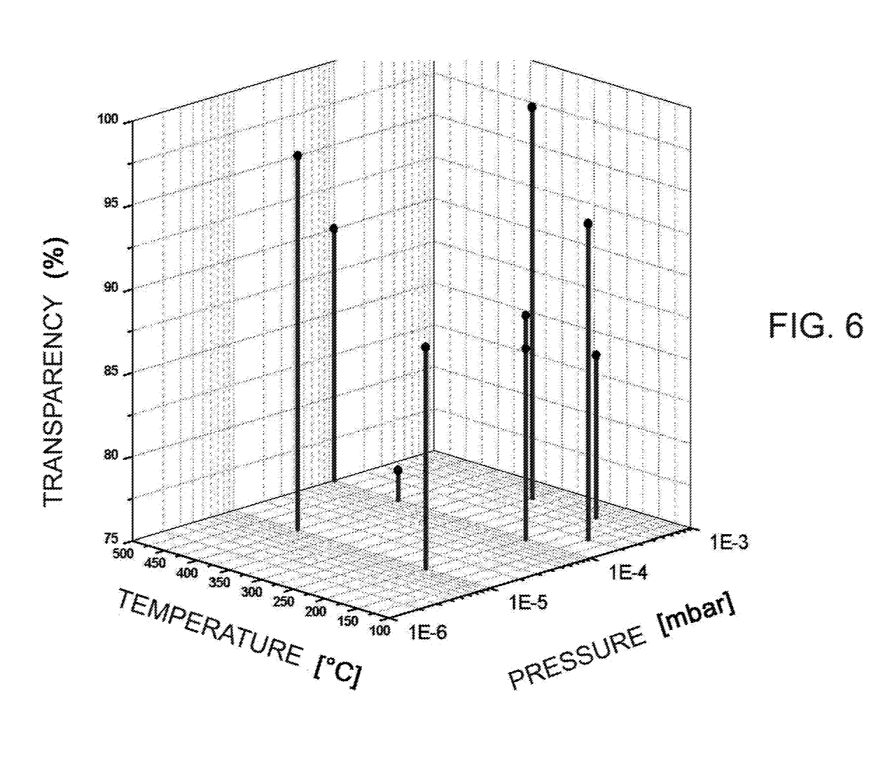

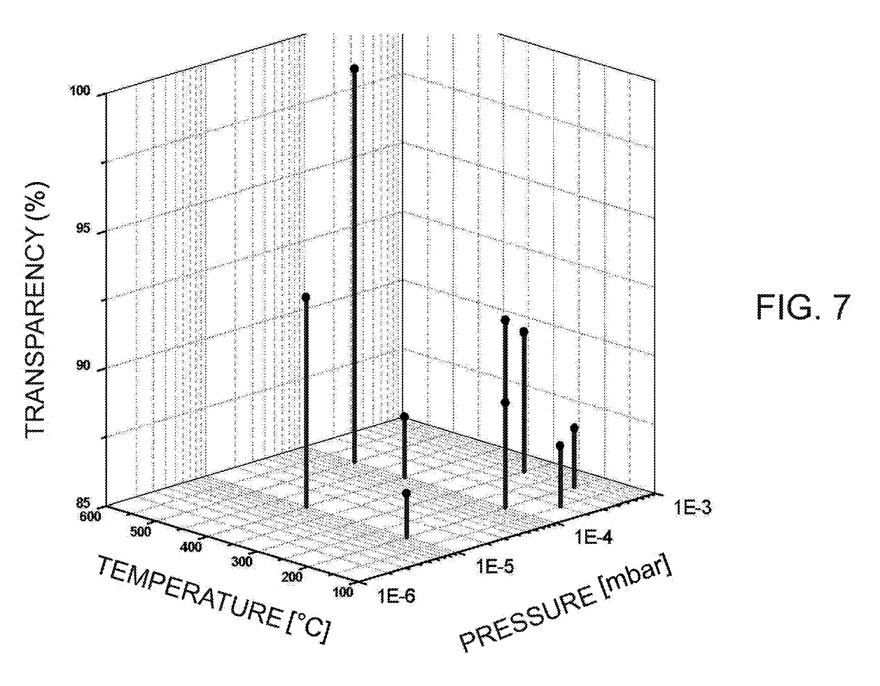

By varying the deposition parameters as in the resistivity example, one obtains that the transparency of the films deposited on the glass substrate varies from 78% to 97% at the wavelength of 550 nm (FIG. 6) and from 87 to 97% at the wavelength of 750 nm (FIG. 7).

### Morphology

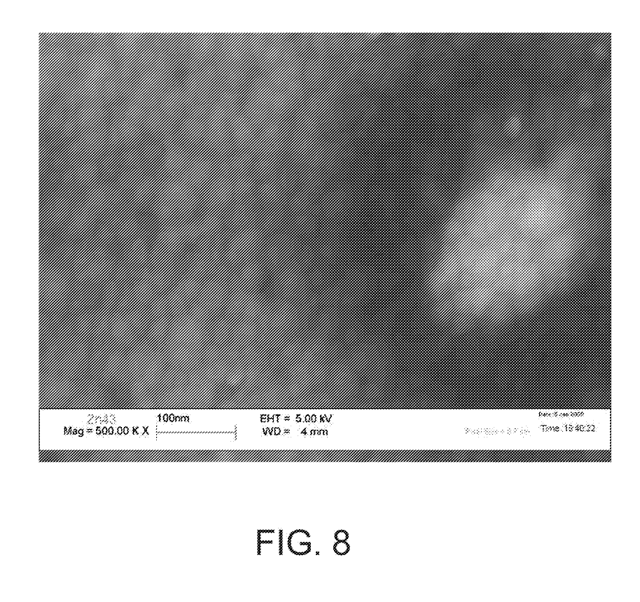

FIG. 8 shows the example of the morphology of films deposited on glass or quartz substrates and studied by means of the scanning electron microscopy method. FIG. 8 shows a film deposited at a glass substrate temperature T=300° C. and an oxygen pressure in the deposition chamber of p=5*10⁻⁵ mbar. The morphology of the film corresponds to that of a crystalline film with low surface roughness (typical ZnO film deposited also by means of a method such as PLD) with a thickness of 200 nm. The film demonstrates low resistivity due to high crystallinity of the film (relaxation of structural disorder) ρ=1.11 mΩ-cm.

### Roughness

The morphological measurements of the ZnO deposited films obtained by means of the AFM method have revealed the relatively low roughness (8-10 nm on a thickness of 180-200 nm) and the presence of a small number of defects such as pinholes of the films.

The ZnO film with the lowest resistivity was deposited by using the following conditions:

oxygen pressure in the deposition chamber p=5*10⁻⁵ mbar

substrate temperature T=300° C.

pulsed electron and plasma acceleration voltage V=−16 kV

deposition time t=2 hours

deposition frequency f=2 Hz

distance between target and substrate d=40 mm

The following results were achieved:

film thickness s=200 nm

resistivity ρ=1.11 mΩ-cm

### Deposition of AZO

### Optimized Parameters of AZO Deposition, Properties of Deposited Films

The deposition parameters of AZO films (98% ZnO and 2% Al by weight) were selected equal to those indicated above for ZnO.

The physical properties of AZO films were studied by means of the measurements of electrical resistivity (van de Pauw method), optical transparency in the visible and infrared wavelength range.

### Electrical Resistivity

Films of zinc oxide doped with aluminum (AZO) deposited on glass demonstrate a similar dependency on deposition parameters (substrate temperature, oxygen pressure in the deposition chamber) as ZnO films. The minimum of resistivity (ρ=0.16 mΩ-cm) is achieved for pressure parameters p=2×10⁻⁵ mbar of oxygen and the substrate temperature T=300° C., the pressure of the resulting film being 50 nm.

### Transmittance

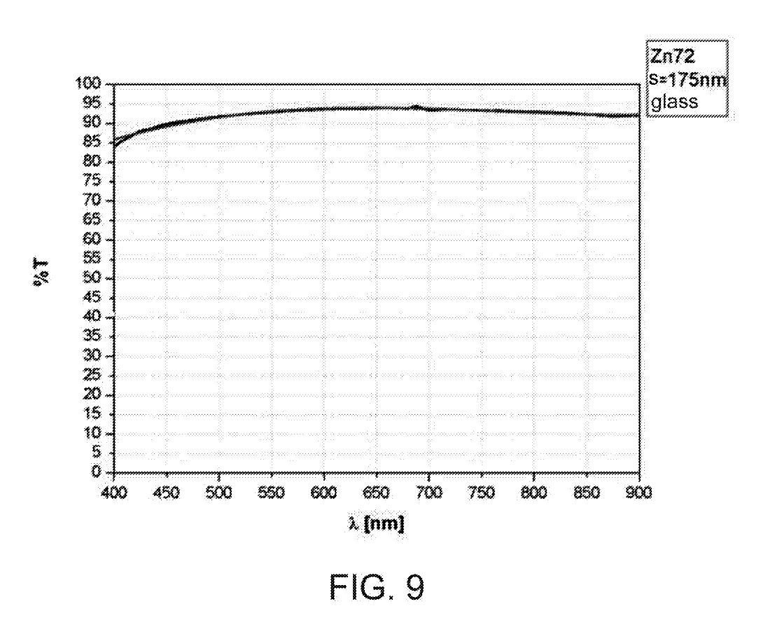

For AZO films deposited on a rigid support (glass) at a pressure of 2.5·10⁻⁵ mbar and at a substrate temperature of 300° C., the average value of transparency is T=91% in the 400-800 nm wavelength range (FIG. 9).

The AZO film with the lowest resistivity was deposited by using the following conditions:

oxygen pressure in the deposition chamber p=2·10⁻⁵ mbar

substrate temperature T=300° C.

pulsed electron and plasma acceleration voltage V=−16 kV

deposition time t=2 hours

deposition frequency f=2 Hz

distance between target and substrate d=40 mm

The following results were achieved:

film thickness s=50 nm

resistivity ρ=0.167 mΩ-cm

Deposition of Doped Zinc Oxide by Multiple Ablation. PPD Ablation with Multiple Guns

Deposition of doped material or a material grown by kinematic means (a system not in thermodynamic equilibrium) requires the use of two or more guns working simultaneously. One of the guns is used to deposit the base material and the others are then used for ablation and deposition of the doping materials in the suitable quantities. Such system allows to create alloys and dopings of systems which cannot be created in bulk form (for example due to phase separation, which prevents this combination of the materials or the selected concentrations of dopants). Moreover, it is possible to create systems grown in conditions of lack of thermodynamic equilibrium (such as for example amorphous systems or crystalline systems but with structurally incompatible dopants incorporated kinematically—for example zinc oxide doped with the magnetic species—Fe, Mn, Co, Ni and the like).

The PPD system of two or more guns is composed, in addition to the parts already mentioned for the single-gun system, of two or more guns with the corresponding power supplies and the unit for mutual synchronization and “timing” of the guns. The synchronization and “timing” unit performs two functions. The first function must ensure the required ratio between the amount of base material and dopants by controlling the frequencies of the deposition of the corresponding guns. The second function relates to the “timing” of the formation of the plume of base material and dopant. The sequence of the events for ablation of the base material and of the dopant must be such as to ensure the overlap of the plumes of the two materials which is suitable to provide the sought chemical reactions in the plasma phase. The interval between the ablation of one material and ablation of the other material varies between 0 and 500 ns, depending on the combination of materials and on the type of reaction expected.

Deposition of P-Type ZnO Doped with Li by Using Two Guns

The ZnO material mentioned above are all of the n-type (i.e the electrons are the majority charge carriers). In the subsequent section the p-type of ZnO is used. In the p-type ZnO, the holes are the majority charge carriers.

The PPD system with two PPD guns is demonstrated in FIG. 10. Each gun has its own target: one is pure ZnO and the second one can be composed of ZnO and the dopant (as lithium oxide) at different concentrations or pure lithium oxide (the composition of the second target is (Li₂O)ₓ+(ZnO)₁₋ₓ, where 0≦x≦1; preferably, 0.03≦x≦0.1). The amount of dopant (lithium) is controlled by means of the concentration of the dopant in the target and by means of the ratio between the ablation frequency of the base material (ZnO) and the dopant ((Li₂O)ₓ+(ZnO)₁₋ₓ). The plumes generated by two corresponding targets overlap on a substrate which is fixed on, and heated by, a heating substrate carrier. The temperature of the heating unit can be controlled from ambient temperature to 500° C., preferably from 150° C. to 350° C. During ablation and deposition, the target and the substrate rotate at a frequency from 0.1 to 5 Hz, preferably at a frequency from 0.5 to 1 Hz. The deposited material forms a thin film of ZnO doped with Li with a thickness from 10 to 1000 nm, preferably from 100 to 200 nm. The remaining deposition parameters are equal to the ones for the deposition of n-type ZnO films mentioned above.

Hall-effect measurements demonstrate that the conductivity of films of ZnO doped with Li prepared by means of the PPD method is of the p type with a concentration of charge carriers (holes) of approximately 5*10¹⁷ cm⁻³, mobility is approximately 1.7 cm²/Vs and typical resistivity is 6.2 Ωcm.

1. A method for depositing a metal oxide film on a surface of a supporting body for said film, comprising the steps of:
providing a deposition chamber;
providing a pulsed beam of electrons and plasma in said deposition chamber;
supplying a supporting body in said deposition chamber, said supporting body having a deposition surface;
providing a target body made of a material which comprises said metal oxide in said deposition chamber, said target body having a target surface;
providing a plume of metal oxide ablated from said target surface by means of the impact of said pulsed beam of electrons and plasma against said target surface; and
depositing a metal oxide film on said deposition surface by means of the contact of said plume with said deposition surface.

2. The method according to claim 1, wherein said metal oxide is a transparent conducting oxide, particularly a metal oxide selected from the group constituted by zinc oxide and zinc oxide doped with aluminum, or lithium or other dopants.

3. The method according to claim 1, wherein said supporting body is a supporting body made of a transparent material, or a non transparent material.

4. The method according to claim 1, wherein said supporting body is a supporting body which is flexible or rigid.

5. The method according to claim 1, wherein said supporting body is a body made of solid inorganic material.

6. The method according to claim 5, wherein said supporting body is made of a material selected from the group constituted by glass, quartz, CdS, ZnSe, metals, and inorganic semiconductors.

7. The method according to claim 1, wherein said supporting body is a body made of solid organic material.

8. The method according to claim 7, wherein said supporting body is made of a material selected from the group constituted by polymers such as polyesters, polyolefines, polyimides, phenolic resins, polyanhydrides, conducting polymers, conjugated polymers, fluoropolymers, silicone rubbers, silicone polymers, biopolymers, copolymers, block copolymers such as polycarbonate, PTFE, PET, PNT, PEDOT, polyaniline, polypyrrole, polythiophenes, polyparaphenylenes (PPV), polyfluorenes, and molecular solids like molecular semiconductors, molecular crystals, molecular thin films, molecular dyes, such as AlQ3, thiophene oligomers, PPV oligomers, pentacene, tetracene, rubrene, NPB, fullerenes, carbon nanotubes and fullerides.

9. The method according to claim 1, wherein said electron and plasma beam has a pulsed energy from 500 keV to 50 keV, particularly from 5 keV to 20 keV.

10. The method according to claim 1, wherein a pressure from 10⁻⁶ to 10⁻² mbar, preferably from 10⁻⁵ to 5×10⁻³ mbar, is maintained in said deposition chamber.

11. The method according to claim 1, wherein in said deposition chamber there is a working gas selected among the group constituted by oxygen, argon, nitrogen and mixtures of methane and argon, hydrogen and argon, boranes, diboranes and ammonia.

12. The method according to claim 1, wherein said beam of electrons and plasma is a pulsed beam of electrons and plasma generated with a frequency from 0.1 Hz to 500 Hz, particularly from 1 Hz to 19 Hz.

13. The method according to claim 1, wherein said pulsed beam of electrons and plasma is a beam of electrons and plasma generated by using an average current from 1 mA and 50 mA, particularly from 1 to 5 mA.

14. The method according to claim 1, wherein said pulsed beam of electrons and plasma is a beam of electrons and plasma generated by using a potential difference between an anode and a cathode from 500 V to 50 ke V, particularly from 12 to 18 kV.

15. The method according to claim 1, wherein said target surface and said deposition surface are arranged at a mutual distance from 5 mm to 500 mm.

16. The method according to claim 5, wherein said support has a temperature comprised between ambient temperature and 550° C.

17. The method according to claim 7, wherein said support has a temperature comprised between ambient temperature and 350° C.

18. The method according to claim 1, wherein it further comprises the step for adjusting a distance between said target surface and said deposition surface.

19. The method according to claim 1, wherein it further comprises the step for adjusting the temperature of said supporting body.

20. The method according to claim 1, wherein said target body is subjected to a rotary motion during said deposition step.

21. The method according to claim 1, wherein said deposition supporting body is subject of rotary motion during said deposition step.

22. The method according to claim 1, wherein said supporting body and said target body are positioned within said deposition chamber so that said plume makes contact with said deposition surface.

23. A method for depositing a film of a metal oxide doped with a doping agent on a surface of a supporting body for said film, comprising the steps of:
providing a deposition chamber;
providing a first and a second pulsed beam of electrons and plasma in said deposition chamber;
supplying a supporting body in said deposition chamber, said supporting body having a deposition surface;
providing in said deposition chamber a first and a second target body, said first target body being made of a material which comprises said metal oxide, said second target body being made of a material which comprises said doping agent, said first target body having a first target surface and said second target body having a second target surface;
providing a plume of metal oxide ablated from said first target surface by means of the impact of said first pulsed beam of electrons and plasma against said first target surface, and a plume of said doping agent ablated from said second target surface by means of the impact of said second pulsed beam of electrons and plasma against said second target surface; and
depositing simultaneously said metal oxide and said doping agent on said deposition surface by means of the contact of said plume of metal oxide and of said plume of doping agent with said deposition surface, thereby a film of said metal oxide doped with said doping agent is obtained on said deposition body.

24. The method according to claim 23, wherein said metal oxide is type-p ZnO and said doping agent is a Li containing compound, as Li2O.

25. The method according to claim 23, wherein said metal oxide is ZnO and said doping agent comprises magnetic species.

26. A metal oxide film which can be obtained by deposition on a surface of a supporting body by means of the method according to claim 1.
